(19) United States
(12) Patent Application Publication
(10) Pub. No.: US 2025/0176296 A1
(43) Pub. Date: May 29, 2025

(54) SINGLE PHOTON AVALANCHE DIODE COMPRISING A CAPACITIVE EFFECT PASSIVATION STRUCTURE

(71) Applicant: COMMISSARIAT À L’ENERGIE ATOMIQUE ET AUX ENERGIES ALTERNATIVES, PARIS (FR)

(72) Inventors: Norbert MOUSSY, GRENOBLE CEDEX 9 (FR); Mickaël CAVELIER, GRENOBLE CEDEX 9 (FR)

(21) Appl. No.: 18/955,103

(22) Filed: Nov. 21, 2024

(30) Foreign Application Priority Data
Nov. 24, 2023 (FR) 2313040

(51) Int. Cl. H01L 27/146

(52) U.S. Cl. CPC H10F 39/807; H10F 39/028

(57) ABSTRACT

A single photon avalanche diode includes a semiconductor substrate doped with a first conductivity type and having a first face and a second face opposite to the first face; a peripheral isolation structure delimiting an active region of the semiconductor substrate, the peripheral isolation structure extending into the semiconductor substrate from the first face towards the second face; a semiconductor region doped with a second conductivity type opposite to the first conductivity type, extending into the active region of the semiconductor substrate from the first face towards the second face; and a capacitive effect passivation structure disposed inside a first trench which extends into the semiconductor region, the capacitive effect passivation structure extending in contact with the semiconductor region and being configured to form a first electric charge accumulation layer in the semiconductor region at the interface with the first trench.

### CROSS-REFERENCE TO RELATED APPLICATIONS

This application claims priority to French Patent Application No. 2313040, filed Nov. 24, 2023, the entire content of which is incorporated herein by reference in its entirety.

### FIELD

The technical field of the invention is that of Single Photon Avalanche Diodes, also referred to as SPADs.

### BACKGROUND

A Single Photon Avalanche Diode (SPAD) is a photodiode comprising a PN junction reverse biased to a voltage above its breakdown voltage. When no electric charge is present in the depletion zone (also referred to as the space charge region) of the PN junction, the photodiode is in a pseudo-stable, non-conducting state. When an electric charge generated by the absorption of a photon is injected into the depletion zone, if the speed of travel of this charge in the depletion zone is sufficiently high, i.e. if the electric field in the depletion zone is sufficiently intense, the photodiode enters avalanche. A single photon is thus capable of generating a measurable electrical signal in a very short period of time.

SPADs have high detection sensitivity and very short response times, making them excellent candidates for time-of-flight measurement in telemetry, facial recognition and LiDAR (Light Detection And Ranging) applications. They can detect very low-intensity radiation and are also used for single photon detection and photon counting.

The PN junction is typically formed between a substrate doped with a first conductivity type and a localised region (in the substrate) doped with a second, opposite to the first, conductivity type. One problem that arises in SPADs with a horizontal PN junction (i.e. parallel to the front and rear faces of the substrate) is that of collecting photogenerated charges deep into the substrate, at a distance away from the photodiode avalanche zone (i.e. the part of the depletion zone in which the electric field is sufficiently intense for the avalanche to be triggered by a single charge). Indeed, beyond some distance from the PN junction, the electric field resulting from the reverse bias of the PN junction is cancelled or strongly attenuated, and can no longer drive the photogenerated charges towards the avalanche zone. Only random diffusion in the substrate is then likely to drive the photogenerated charges towards the avalanche zone, with a non-negligible probability that the photogenerated charges never reach the avalanche zone or reach it with a significant delay. This problem arises especially when it is desired to collect photogenerated charges under the effect of high-wavelength radiation, for example radiation with a wavelength of between 750 and 1200 nm in silicon.

FIG. 1 is a schematic cross-section view of a SPAD-type photodiode 1 described in international application WO2018/050996A1.

The photodiode 1 comprises a substrate 10 made of P-type doped silicon and a localised region 11 made of N-type doped silicon, extending through the substrate 10, along a substantially vertical direction, i.e. substantially perpendicular to the upper face 10a of the substrate 10. The localised region 11 is, for example, in the form of a tube with a substantially vertical central axis. The substrate 10 and the localised region 11 form the anode and cathode, respectively, of the photodiode 1. An avalanche zone of the photodiode 1 is located at the PN junction formed between the substrate 10 and the side surfaces of the localised region 11. This avalanche zone extends into the substrate 10 along a substantially vertical direction. This configuration enables efficient collection of photogenerated charges deep into the substrate 10.

The photodiode 1 further comprises:
a P-type lightly doped layer 12 (P⁻ doping), with a doping level lower than that of the substrate 10, covering the lower face 10b of the substrate 10;
a P-type doped support layer 13, with a doping level higher than that of the P-type lightly doped layer 12, covering the P-type lightly doped layer 12; and
an N-type lightly doped region 14 (N⁻), with a doping level lower than that of the localised region 11, laterally surrounding the upper part 11a of the localised region 11.

The P-type lightly doped layer 12 and the N-type lightly doped region 14 decrease the electric field at the upper and lower parts of the PN junction (due to their lower doping level) and therefore reduce the risk of inadvertent triggering avalanche due to charges generated by silicon surface defects.

The localised region 11 is formed by etching a trench 15 from the upper face 10a of the substrate 10, this trench 15 passing through the N-type lightly doped region 14, the substrate 10 and stopping in the P-type lightly doped layer 12, and then by filling the trench 15 with an N-type doped polycrystalline silicon.

However, surfaces delimiting the trench 15 have many defects caused by etching, which generate a dark current in the presence of an electric field.

Besides, patent U.S. Pat. No. 11,387,379B2 describes an avalanche photodetector for single photon detection whose detection principle is not based on a PN junction. This photodetector is supposed not to suffer from the drawbacks of PN junction SPADs, such as the high dark current caused by silicon defects.

FIG. 2 is a schematic cross-section view of the avalanche photodetector 2 described in that patent. The photodetector 2 comprises a P-type doped semiconductor substrate 20 and a peripheral structure 21 referred to as CDTI (Capacitive Deep Trench Isolation), extending through the semiconductor substrate 20 and surrounding an active region of the semiconductor substrate 20 for photon absorption. The CDTI peripheral structure 21 forms a vertical gate structure. It is formed by etching a trench 22 into the substrate 20, coating the side walls of the trench 22 with a layer of insulating material 210 (such as a thermal oxide) and then filling the remainder of the trench 22 with a conductive material 211 (such as polycrystalline silicon).

The CDTI peripheral structure 21 enables formation of an electron accumulation layer in the P-doped semiconductor substrate 20, at the interface with the layer of insulating material 210. In other words, it enables formation of a doping type inversion layer, as in the channel region of a MOS transistor. This inversion layer yields an electric field E which attracts an electron (photogenerated by the absorption of a photon hv) towards the interface between the layer of insulating material 210 and the semiconductor substrate 20. This electron collides with atoms of the semiconductor substrate 20, thereby releasing other electrons and causing the avalanche effect.

The electron accumulation layer, or doping type inversion layer, is equivalent to a thin, N-type highly doped layer. The electric field E near the interface is indeed high and abrupt, so much so that it causes the appearance of a band-to-band parasitic tunneling current. However, this parasitic tunneling current considerably increases the photodetector dark current.

### SUMMARY

There is therefore a need to provide a device for the detection of a single photon which has a low dark current.

According to an aspect of the invention, this need tends to be satisfied by providing a single photon avalanche diode comprising:
a semiconductor substrate doped with a first conductivity type and having a first face and a second face opposite to the first face;
a semiconductor region doped with a second conductivity type opposite to the first conductivity type, extending into the semiconductor substrate from the first face towards the second face; and
a capacitive effect passivation structure disposed inside a first trench which extends into the semiconductor substrate from the first face towards the second face, the capacitive effect passivation structure extending in contact with the semiconductor region and being configured to form a first electric charge accumulation layer in the semiconductor region at the interface with the first trench.

The first electric charge accumulation layer formed in the semiconductor region makes it possible to passivate surface defects created by etching the first trench and to eliminate any electric field at the interface with the first trench. Thus, these defects do not generate dark current.

In an embodiment, the capacitive effect passivation structure comprises a first dielectric layer and a first electrically charged layer separated from the semiconductor region by the first dielectric layer.

Alternatively, the capacitive effect passivation structure comprises a first dielectric layer and an electrode separated from the semiconductor region by the first dielectric layer.

In first and second embodiments, the diode further comprises a peripheral isolation structure delimiting an active region of the semiconductor substrate, the peripheral isolation structure extending into the semiconductor substrate from the first face towards the second face.

Beneficially, the peripheral isolation structure is disposed inside a second trench and configured to form a second electric charge accumulation layer in the semiconductor substrate at the interface with the second trench.

In an embodiment of the invention, the peripheral isolation structure comprises a second dielectric layer and a second electrically charged layer separated from the active region of the semiconductor substrate by the second dielectric layer.

It may further comprise an opaque material layer separated from the active region of the semiconductor substrate by the second electrically charged layer and the second dielectric layer.

In a third embodiment, the capacitive effect passivation structure surrounds the semiconductor region, which in turn surrounds an active region of the semiconductor substrate.

According to a development of this third embodiment, the capacitive effect passivation structure comprises an opaque material layer.

Further to the characteristics just discussed in the preceding paragraphs, the diode according to the first aspect of the invention may have one or more complementary characteristics from among the following, considered individually or according to any technically possible combinations:
the semiconductor region surrounds the passivation structure by capacitive effect;
the diode further comprises a contacting zone of the semiconductor region;
the contacting zone is disposed on the capacitive effect passivation structure in the first trench;
the contacting zone extends into the semiconductor region;
the diode further comprises a contact pad electrically connected to the semiconductor region by the contacting zone;
the diode further comprises a first electric field reducing layer disposed on the first face of the semiconductor substrate; and
the diode further comprises a second electric field reducing layer disposed on the second face of the semiconductor substrate.

A second aspect of the invention relates to a method for manufacturing a single photon avalanche diode, comprising the following steps of:
etching a first trench in a semiconductor substrate doped with a first conductivity type and having a first face and a second face opposite to the first face, the first trench extending from the first face towards the second face;
forming a doped semiconductor region of a second conductivity type opposite to the first conductivity type, the semiconductor region being partly delimited by the first trench and extending into the semiconductor substrate from the first face towards the second face; and
forming a capacitive effect passivation structure in the first trench, the capacitive effect passivation structure being configured to form a first electric charge accumulation layer in the semiconductor region at the interface with the first trench.

In an embodiment, forming the semiconductor region comprises the following sub-steps of:
epitaxially forming a doped semiconductor layer on a side surface of the first trench, the doped semiconductor layer comprising doping impurities; and
performing diffusion annealing to laterally diffuse the doping impurities from the doped semiconductor layer into the semiconductor substrate.

In one alternative embodiment, the semiconductor region is formed by gas phase diffusion doping from a side surface of the first trench.

### BRIEF DESCRIPTION OF THE FIGURES

Further characteristics and benefits of the invention will become clearer from the description thereof given below, by way of indicating and in no way limiting purposes, with reference to the appended figures, including:

FIG. 1, previously described, schematically represents a single photon avalanche diode according to prior art;

FIG. 2, previously described, schematically represents an avalanche photodetector according to prior art;

FIG. 3 is a schematic cross-section view of a single photon avalanche diode according to a first embodiment of the invention;

FIG. 4 schematically represents the behaviour of the diode of FIG. 3 under reverse bias;

FIG. 5 is a schematic cross-section view of a single photon avalanche diode according to a second embodiment of the invention;

FIG. 6 is a schematic cross-section view of a single photon avalanche diode according to a third embodiment of the invention;

FIG. 7 is a schematic partial top view of a photodetector comprising a plurality of single photon avalanche diodes;

FIGS. 8A to 8I represent steps of a method for manufacturing the single photon avalanche diode according to FIG. 3.

For greater clarity, identical or similar elements are marked with by identical reference signs throughout the figures.

### DETAILED DESCRIPTION

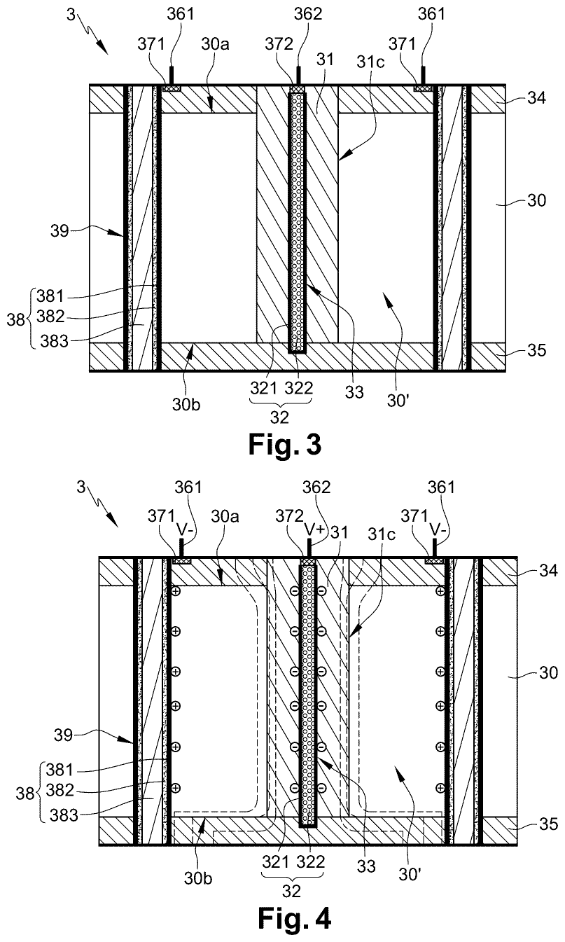

In the following description, the terms “front”, “rear”, “upper”, “lower”, “top”, “bottom”, “horizontal”, “vertical”, “lateral”, etc. used to qualify position or orientation of some elements refer to the orientation of FIGS. 3-6 and 8A-8I. Furthermore, unless otherwise specified, the terms “approximately”, “substantially” and “in the order of” mean to within 5%, or, when they relate to absolute or relative angles or angular orientations, to within 5 degrees.

FIGS. 3, 5 and 6 represent different embodiments of a single photon avalanche diode 3 in schematic cross-section views. The single photon avalanche diode 3 may be indifferently referred to as a “diode 3”, “SPAD 3” or “photodiode 3”.

In common with all these embodiments, the diode 3 comprises:
a semiconductor substrate 30 doped with a first conductivity type, having a first face 30a and a second face 30b opposite to the first face 30a;
a semiconductor region 31 doped with a second conductivity type opposite to the first conductivity type, extending into the semiconductor substrate 30 from the first face 30a towards the second face 30b;
a capacitive effect passivation structure 32 extending in contact with the semiconductor region 31.

The semiconductor substrate 30 (hereinafter simply designated “substrate 30”) and the semiconductor region 31 are, in an embodiment, formed of the same semiconductor material, for example silicon.

The first and second faces 30a-30 of the substrate 30 extend along substantially parallel planes. The first face 30a corresponds (in the orientation of the figures) to the front or upper face of the substrate 30, while the second face 30b corresponds to its rear or lower face. The thickness of the substrate 30 can be between 1 μm and 25 μm, such as between 5 μm and 20 μm.

In an embodiment, the semiconductor region 31 extends along a direction substantially perpendicular to the first face 30a. Beneficially, it passes through the substrate 30 (in other words, it extends over the entire thickness of the substrate 30).

The semiconductor region 31 is a so-called “localised” region, as it occupies only part of the volume of the substrate 30. It has a side surface 31c, at least one part of which is in contact with the substrate 30, thus achieving a PN junction which extends deep into the substrate. In an embodiment, the PN junction extends along a direction substantially perpendicular to the first face 30a.

When the substrate 30 is P-type doped and the semiconductor region 31 is N-type doped, the substrate 30 and the semiconductor region 31 form the anode and cathode of the diode 3, respectively. Conversely, when the substrate 30 is N-type doped and the semiconductor region 31 is P-type doped, the substrate 30 and the semiconductor region 31 form the cathode and anode of the diode 3, respectively.

The diode 3 comprises a depletion zone, also referred to as a space charge region, which extends laterally on either side of the PN junction. Avalanche of the diode 3 occurs in a so-called active part of this depletion zone.

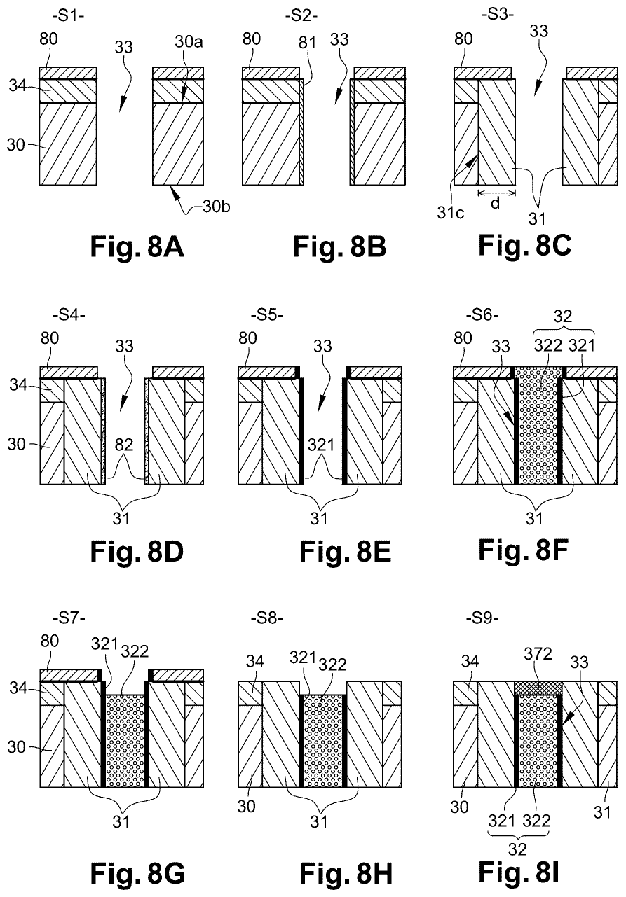

The capacitive effect passivation structure 32 (hereinafter simply designated “passivation structure 32”) is disposed inside a first trench 33, which partly delimits the semiconductor region 31 and extends into the semiconductor region 31. As subsequently described with reference to FIGS. 8C and 8D, the first trench 33 serves to form the semiconductor region 31.

The passivation structure 32 extends in contact with the semiconductor region 31, and, in an embodiment, along a direction substantially perpendicular to the first face 30a of the substrate. Beneficially, it passes through the substrate 30 (in other words, it extends over the entire thickness of the substrate 30).

As described hereinafter in connection with FIG. 4, the capacitive effect passivation structure 32 is configured to form a first electric charge accumulation layer in the semiconductor region 31 at the interface with the first trench 33.

In the embodiments illustrated, the diode 3 further comprises a first electric field reducing layer 34 disposed on the first face 30a of the substrate 30 (in other words on the front face) and/or a second electric field reducing layer 35 disposed on the second face 30b of the substrate 30 (on the rear face). The first and second electric field reducing layers 34-35 are each formed of a N- or P-type doped semiconductor material, which has a concentration of doping impurities (of the donor or acceptor type respectively) lower than the concentration of doping impurities of the substrate 30. This semiconductor material is, in an embodiment, silicon.

In an embodiment of the invention, the first electric field reducing layer 34 (on the front face) has the same type of conductivity as the substrate 30 (i.e. the first type of conductivity) and the second electric field reducing layer 35 (on the rear face) is of the opposite type of conductivity (i.e. the second type of conductivity).

Each of the first and second electric field reducing layers 34-35 can have a thickness of between 50 nm and 1 μm, for example equal to 1 μm.

The semiconductor region 31 may extend from the upper face of the first electric field reducing layer 34, pass through this first layer 34 and the substrate 30, and be interrupted on the upper face of the second electric field reducing layer 35 or in this second layer 35.

Likewise, the first trench 33 may extend from the upper face of the first electric field reducing layer 34, pass through this first layer 34 and the substrate 30, and be interrupted on the upper face of the second electric field reducing layer 35 or in the second layer 35.

The diode 3 further comprises at least one first contact pad 361 electrically connected to the substrate 30 and at least one second contact pad 362 electrically connected to the semiconductor region 31. These contact pads 361-362 make it possible to apply electrical potentials to the substrate 30 and to the conducting region 31, and thus to bias the PN junction of the diode 3. They are made of metal, for example (in which case these are referred to as contact metallisations).

The diode 3 may comprise several first contact pads 361 distributed in such a way as to even out electrical potential applied to the substrate 30 and the collection of charge carriers, as illustrated in the cross-section views of FIGS. 3 to 5. On the contrary, it may include only one second contact pad 362 (the semiconductor region 31 being of much smaller extent than the substrate 30).

Each first contact pad 361 is, in an embodiment, disposed on and in contact with the upper face of the first electric field reducing layer 34.

For each first contact pad 361, a first substrate contacting zone 371, for example made of a doped semiconductor material of the same conductivity type as the substrate 30 but having a higher concentration of doping impurities, may extend from the upper face of the first electric field reducing layer 34 towards the substrate 30, in order to minimise contact resistance (between the first contact pad 361 and the substrate 30). The first contact pad 361 is then electrically connected to the substrate 30 by the first contacting zone 371. It is beneficially disposed on and in contact with this first contacting zone 371.

The second contact pad 362 is, in an embodiment, located at the same level as the first contact pad(s) 361, in other words at the level of the upper face of the first electric field reducing layer 34 (which coincides here with the upper face of the semiconductor region 31). A second zone 372 for contacting the semiconductor region, for example made of a doped semiconductor material of the same conductivity type as the semiconductor region 31 but having a higher concentration of doping impurities, is beneficially provided to reduce contact resistance (between the second contact pad 362 and the semiconductor region 31). The second contact pad 362 is then electrically connected to the semiconductor region 31 by the second contacting zone 372. It is beneficially disposed on and in contact with this second contacting zone 372.

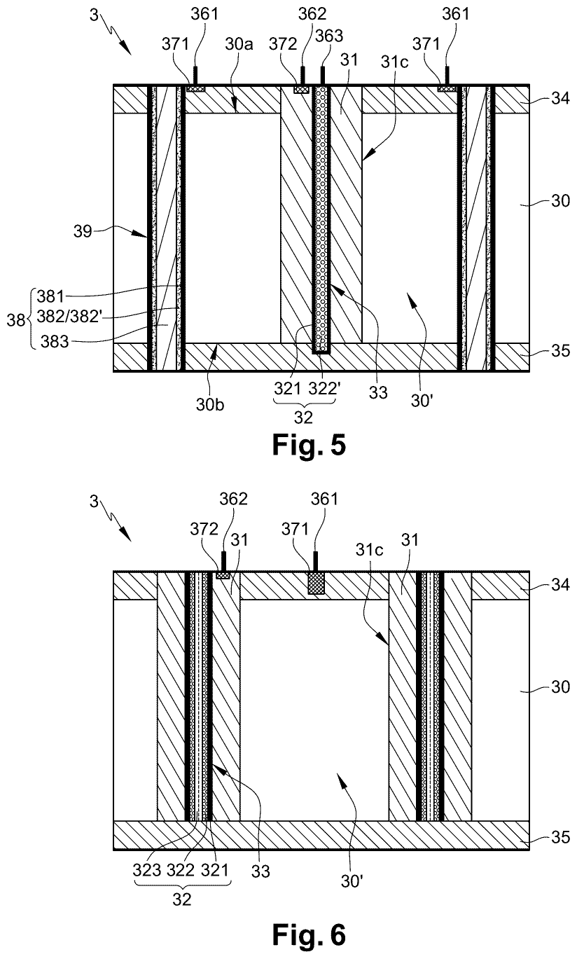

The position of this second contacting zone 372 (and therefore of the second contact pad 362) differs according to the embodiments of the diode 3. In the embodiment of FIG. 3, the second contacting zone 372 is located in the first trench 33, on the passivation structure 32. The second contacting zone 372 and the passivation structure 32 are thus aligned with each other. In other words, the second contacting zone 372 does not laterally extend beyond the passivation structure 32. It is therefore in contact with the semiconductor region 31 via its side surface only. In the embodiments of FIGS. 5 and 6, the second contacting zone 372 extends into the semiconductor region 31. It is then in contact with the semiconductor region 31 via its side surface, but also its lower surface.

The first and second contacting zones 371-372 are, in an embodiment, made of (doped) silicon.

In the absence of the first electric field reducing layer 34, the first and second contact pads 361-362 are disposed at the front face 30a of the substrate 30 (rather than at the upper face of the first electric field reducing layer 34).

In operation, the cathode of diode 3 is biased to a positive potential V+ and the anode of the photodiode is biased to a negative potential V− (via contact pads 361-362), so that the cathode-anode voltage of the diode is greater than the avalanche voltage (in absolute value). When diode 3 is thus reverse biased, an electric field appears at the PN junction.

The operation of diode 3 is described hereinafter in connection with FIG. 4. This figure shows the diode of FIG. 3 under reverse bias, but the operation described is common to all the embodiments.

In FIG. 4, the dotted lines represent equipotential lines in the structure when diode 3 is reverse biased. In this example, the substrate 30 is P-doped and makes up the anode, while the semiconductor region 31 is N-doped and makes up the cathode. The closer the equipotential lines are to each other, the stronger the electric field.

As is apparent from the figure, since the level of doping (i.e. the concentration of doping impurities) of the first and second electric field reducing layers 34-35 is lower than the doping level of the substrate 30, the equipotential lines are less constricted at the upper (at the interface between the first layer 34 and the upper part of the semiconductor region 31) and lower (at the interface between the second layer 35 and the lower part of the semiconductor region 31) parts of the PN junction than at the central part (at the interface between the substrate 30 and the central part of the semiconductor region 31) of the PN junction. As a result, the electric field generated at the upper and lower parts of the PN junction is less intense than the electric field generated at the central part of the PN junction.

The doping impurity concentrations of the substrate 30, the semiconductor region 31 and the first and second electric field reducing layers 34-35, as well as the bias voltage of the diode, are, in an embodiment, selected so that the electric field at the central part of the PN junction is sufficiently strong for the avalanche to be triggered by a single photogenerated charge, for example is greater than 300 kV/cm over a distance of 100 nm to 500 nm along a direction orthogonal to the PN junction, and so that the electric field at the upper and lower parts of the PN junction is sufficiently weak that the avalanche cannot be triggered by a single photogenerated charge, for example is less than 300 kV/cm. By way of example, the breakdown voltage (or avalanche voltage) of the diode is between 10 V and 50 V (absolute values), and the reverse bias voltage of the photodiode is higher than its breakdown voltage by a value between 0.5 and 10 V (absolute values). The concentration of doping impurities in the substrate 30 is, for example, between 5.10¹⁶ cm⁻³ and 7.10¹⁷ cm³. The concentration of doping impurities in the semiconductor region 31 is, for example, between 10¹⁷ cm³ and 10¹⁹ cm 3. The concentration of doping impurities in the first and second electric field reducing layers 34-35 is for example less than 5.10¹⁶ cm⁻³.

The first and second electric field reducing layers 34-35 reduce the risk of inadvertent triggering of avalanche at the ends of the PN junction, this risk being linked to edge effects such as the presence of surface defects in the semiconductor material. However, these layers are optional, as other solutions can be provided to control the risk of inadvertent triggering of the avalanche due to edge effects, for example by varying shape of the upper and lower ends of the semiconductor region 31, or by reducing the doping level of the semiconductor region 31 at its upper and lower ends.

The passivation structure 32 is used to passivate the defects caused by etching the first trench 33, by forming a first accumulation layer of electric charges in the semiconductor region 31, at the interface with the first trench 33. These electric charges have a polarity corresponding to the conductivity type of the semiconductor region 31, i.e. the second conductivity type. This is therefore a true accumulation layer, and not an inversion layer as in the avalanche photodetector of prior art. In the example illustrated in FIG. 4, the semiconductor region 31 is N-doped and the accumulated charges are therefore electrons.

The electric charges come from the surface contact. The accumulation layer provides good electrical continuity between the contact and the rest of the semiconductor region 31 to ensure both static and dynamic equilibrium during avalanche phases.

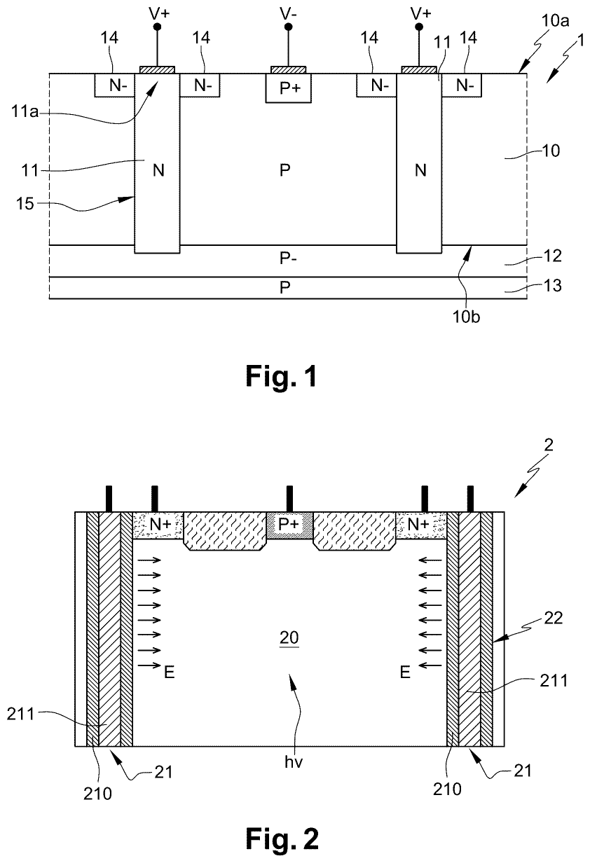

The defects are rendered inactive and the electric field at the level of the first trench 33 is reduced. The dark current of diode 3 is therefore reduced relative to a diode free of a capacitive effect passivation structure, such as that of FIG. 1.

The first trench 33 has a bottom and a peripheral side surface. The bottom of the first trench 33 is here formed by the second electric field reducing layer 35. The peripheral side surface of the first trench 33 is at least partly formed by the semiconductor region 31.

The semiconductor region 31 and the first trench 33 may be arranged so that the peripheral side surface of the first trench 33 entirely consists of the semiconductor region 31.

The peripheral side surface of the first trench 33 is thus at least partly passivated, by virtue of the first charge accumulation layer. In addition to reducing the dark current, this passivation brings the PN junction closer to the first trench 33 (without the risk of activating defects) and thus, more generally, reduces the side dimensions of the diode 3. This reduction in the size of the diode 3 is of particular interest with a view to forming a photodetector comprising a diode array.

The passivation structure 32 may occupy the whole of the first trench 33, as in the embodiments of FIGS. 5 and 6, or only part of the first trench 33, as in the embodiment of FIG. 3 (where the second contacting zone 372 occupies the upper part of the first trench 33).

The passivation structure 32 can assume different configurations.

In the embodiment of FIG. 3, the passivation structure 32 comprises a first dielectric layer 321 and a first electrically charged layer 322 separated from the semiconductor region 31 by the first dielectric layer 321.

The first dielectric layer 321 covers the peripheral side surface of the first trench 33 and, beneficially, the bottom of the first trench 33. It is, in an embodiment, formed of an oxide, for example silicon dioxide (SiO₂).

The first charged layer 322 contains electric charges of opposite polarity to those desired in the semiconductor region 31. It is, in an embodiment, formed of a dielectric material, for example silicon nitride (Si₃N₄) in the case of a positively charged layer, alumina (Al₂O₃) or tantalum pentoxide (Ta₂O₅) in the case of a negatively charged layer. The electric charge surface density of the first charged layer 322 at the interface with the first dielectric layer 321 is, in an embodiment, greater than 10¹² cm⁻².

The first charged layer 322 beneficially occupies the remaining part of the first trench 33. It thus forms the core of the passivation structure 32, while the first dielectric layer 321 makes up the shell of the passivation structure 32.

A benefit of this embodiment is that the passivation structure 32 does not require electrical contact to the front face of the substrate 30, allowing the second contact pad 362 and the second contacting zone 372 to be formed instead (see FIG. 3). The diode 3 can then have a symmetrical configuration relative to the passivation structure 32. Forming the second contacting zone 372 in the first trench 33 limits the contact area on the useful surface of the diode 3, which tends to avoid electric field peaks and therefore inadvertent triggering of the avalanche on the surface.

In the embodiment of FIG. 5, the passivation structure 32 comprises the first dielectric layer 321 described previously and an electrode 322′ separated from the semiconductor region 31 by the first dielectric layer 321, in the manner of a MOS (metal-oxide-semiconductor) gate structure. The electrode 322′ is an electrically conductive layer, for example made of doped polycrystalline silicon or metal. Similarly to the embodiment in FIG. 3, the first dielectric layer 321 and the electrode 322′ can form the shell and the core, respectively, of the passivation structure 32.

During operation of the diode 3, a voltage is applied between the electrode 322′ and the semiconductor region 31 (in addition to the bias voltage of the PN junction) in order to form the first charge accumulation layer. To do this, the diode 3 comprises a third contact pad 363 electrically connected to the electrode 322′ of the passivation structure 32. This third contact pad 363 is, in an embodiment, disposed on and in contact with the upper face of the electrode 322′. Beneficially, it is at the same level as the first and second contact pads 361-362.

In common with the embodiments of FIGS. 3 and 5, the semiconductor region 31 is ring (or tube) shaped and the passivation structure 32 occupies the space inside this ring. In other words, the semiconductor region 31 surrounds the passivation structure 32. The inner side surface of the semiconductor region 31, in contact with the passivation structure 32, is therefore peripheral. The ring formed by the semiconductor region 31 has, in an embodiment, a rectangular cross-section in the cross-sectional plane of the figures and a central axis substantially perpendicular to the first face 30a.

Furthermore, the semiconductor region 31 and the passivation structure 32 are themselves surrounded by a so-called active region 30′ of the substrate 30. The side surface 31c of the semiconductor region 31, outside and in contact with the active region 30′ of the substrate 30, is therefore peripheral. The active region 30′ of the substrate 30 is for photon absorption.

The semiconductor region 31 and the passivation structure 32 are beneficially disposed in the centre of the active region 30′ of the substrate 30.

In addition, the diode 3 beneficially comprises a peripheral isolation structure 38 delimiting the active region 30′ of the substrate 30. The peripheral isolation structure 38 extends into the substrate 30 from the first face 30a towards the second face 30b, and, in an embodiment, along a direction substantially perpendicular to the first face 30a. Beneficially, it passes through the substrate 30.

The peripheral isolation structure 38 may also extend through the first electric field reducing layer 34 and/or the second electric field reducing layer 35, as illustrated in the figures.

The peripheral isolation structure 38 is beneficially disposed inside a second trench 39 and configured to form, by capacitive effect, a second electric charge accumulation layer in the substrate 30, at the interface with this second trench 39. Thus, defects generated by etching the second trench 39, for the purposes of electrical and/or optical insulation of the diode 3, are passivated. In the example illustrated in FIG. 4, substrate 30 is P-doped, so the accumulated charges are holes.

Such a peripheral isolation structure 38 may be referred to as a Capacitive Deep Trench Insulation (CDTI) structure.

Similarly to the passivation structure 32, the peripheral isolation structure 38 may comprise:
a second dielectric layer 381 (such as an oxide such as SiO₂); and
a second electrically charged layer 382 (such as a dielectric such as Si₃N₄, Al₂O₃ or Ta₂O₅) or a second electrode 382′ (of metal or doped polysilicon) separated from the active region 30′ of the substrate 30 by the second dielectric layer 381.

The second trench 39 has an annular shape (to surround the active region 30′ and the semiconductor region 31). The second dielectric layer 381 covers a peripheral side surface of the second trench 39, formed by the active region 30′ of the substrate 30. The second electrically charged layer or electrode occupies all or part of the remainder of the second trench 39.

The peripheral insulating structure 38 may further comprise an opaque material layer 383 separated from the active region 30′ by the second electrically charged layer 382 or the second electrode 382′ and the second dielectric layer 381. This opaque material layer 383, for example made of metal, makes it possible to render the peripheral insulating structure 38 opaque, thus preventing photons emitted in the avalanche zone of the diode 3 from propagating to one or more neighbouring diodes 3 and triggering an avalanche therein. Thus, the peripheral isolation structure 38 is configured to reduce optical crosstalk, in addition to limiting electric charge leakage (electrical insulation). An opaque material layer designates a layer whose transmission factor is less than 20% for wavelengths between 400 nm and 1100 nm.

Alternatively, the peripheral isolation structure 38 can be a deep trench insulation structure, or DTI structure, indeed a structure without the functions of passivating the flanks of the diode 3 by capacitive effect and limiting optical crosstalk.

FIG. 6 represents one embodiment of the diode 3 wherein the capacitive effect passivation structure 32 (disposed inside the first trench 33) and the semiconductor region 31 are both annular (or tubular) in shape. The passivation structure 32 surrounds the semiconductor region 31, which in turn surrounds the active region 30′ of the substrate 30. In other words, the passivation structure 32 is not located at the centre of the diode 3, but at its periphery. The passivation structure 32 is therefore described as a peripheral structure.

The peripheral passivation structure 32 may comprise, similarly to the embodiment of FIG. 3, the first dielectric layer 321 and the first electrically charged layer 322 (separated from the semiconductor region 31 by the first dielectric layer 321). Beneficially, it further comprises an opaque material layer 323 separated from the semiconductor region 31 by the first electrically charged layer 322 and the first dielectric layer 321, to reduce optical crosstalk with one or more neighbouring diodes.

Alternatively, the peripheral passivation structure 32 may comprise the first dielectric layer 321 and the first electrode 322′, as in the embodiment shown in FIG. 5. Optical crosstalk between neighbouring diodes is then decreased by selecting an opaque (conductive) material (such as a metal) to form the first electrode 322′.

In both cases, the peripheral passivation structure 32 then fulfils the electrical insulation function of the peripheral isolation structure 38 described in connection with FIGS. 3 and 5 and, beneficially, the function of limiting optical crosstalk (in the presence of a layer of opaque material).

The benefit of this embodiment is that only one (annular) trench needs to be formed, instead of two.

The diode 3 may here include only a single first contact pad 361 electrically connected to the substrate 30, for example via a first contacting zone 371. This first contact pad 361 is beneficially located in the centre of the upper face of the diode 3 (upper face of the first electric field reducing layer 34 or upper face of the active portion of the substrate 30).

Several diodes 3 according to any of the embodiments described above can be combined in a photodetector, in the form of an array. Each diode 3 then forms a pixel of the array, referred to as a SPAD pixel. The different diodes 3 share the same substrate 30. Each diode 3 comprises an active region 30′ of the substrate 30, a semiconductor region 31 in contact with this active region 30′ (thus forming the PN junction) and a capacitive effect passivation structure 32. The active region 30′ of the substrate 30 is delimited either by the peripheral isolation structure 38 of FIGS. 3 and 5, or by the peripheral passivation structure 32 of FIG. 6. Two neighbouring pixels (in a row or column of the array) may share a portion of the opaque material layer 323, 383 fulfilling the function of optical insulator.

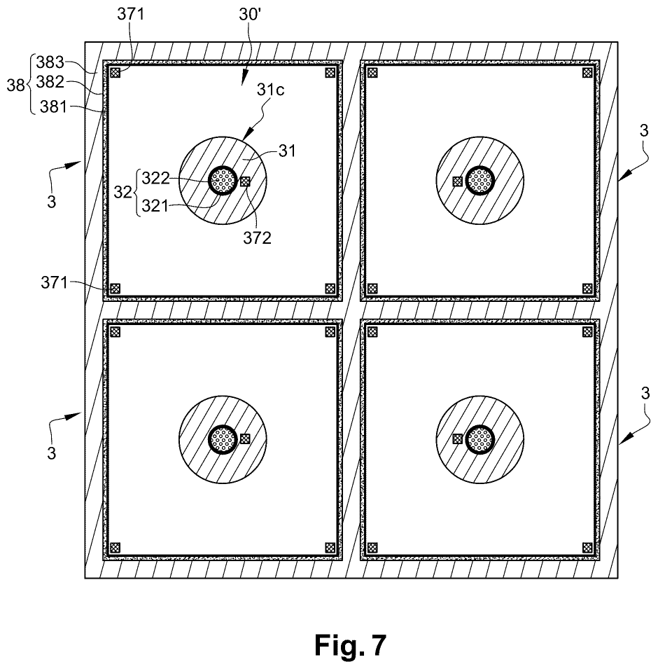

FIG. 7 represents, in a top view, an example of a photodetector comprising an array of diodes 3 or SPAD pixels, here 4 in number. The diodes 3 are in this example in the configuration described in connection with FIG. 3. The active region 30′ has in an embodiment a square shape in a top view and is, for example, between 2 μm and 6 μm on a side. Each diode 3 comprises four first semiconductor zones 731 (and four first contact pads) located in the four corners of the active region 30′, in order to even out electric field and charge collection.

In addition to the array of diodes 3, the photodetector may comprise a circuit for biasing the diodes 3 (to a voltage higher than their avalanche voltage), a read circuit configured to detect avalanche of one or more diodes 3 (and thus a voltage pulse output from the diode), as well as a quenching circuit whose function is to interrupt avalanche of the diode(s) once it has been triggered. These auxiliary circuits have not been represented in the figures and will not be detailed, as the diode embodiments described above are compatible with the auxiliary circuits equipping known SPAD photodetectors.

For diodes 3 according to FIG. 3 or FIG. 5, the read circuit and the quenching circuit are beneficially electrically connected to the second contact pad 362 (or to the second contacting zone 372) of each diode 3, and thus to the semiconductor region 31, since the semiconductor region 31 constitutes the electrode which has the lowest capacitance, due to its smaller surface area compared with the other electrode or doping zones of the diode. For diodes 3 according to FIG. 6, the read circuit and the quenching circuit are beneficially electrically connected to the first contact pad 361 (or to the first contacting zone 371) of each diode 3.

The auxiliary circuits of the photodetector can be gathered in a CMOS (complementary metal oxide semiconductor) technology integrated circuit. This integrated circuit is beneficially bonded to the array of diodes 3, such as on the front face of the substrate 30 (for rear-face illumination of the diodes).

A method for manufacturing diode 3 will now be described. FIGS. 8A to 8I schematically represent a cross-sectional view of steps S1 to S9 of a desired embodiment of the manufacturing method, enabling the diode 3 of FIG. 3 to be obtained.

FIG. 8A represents a step S1 of etching the first trench 33 in the substrate 30, through an etching mask 80. The first trench 33 has, for example, a diameter of between 250 nm and 1 μm and a depth of between 5 μm and 25 μm. The etching mask 80 is, in an embodiment, a hard mask, for example made of oxide.

The first trench 33 is, for example, etched from the upper face of a stack comprising the first electric field reducing layer 34, the substrate 30 and the second electric field reducing layer 35 (not represented). The stack may also comprise a support layer/substrate (not represented), from which the other layers 34, 30, 35 have been formed, for example by epitaxy. The first trench 33 passes through the first electric field reducing layer 34, the substrate 30 and is interrupted at or in the second electric field reducing layer 35.

Steps S2 and S3 in FIGS. 8B and 8C are related to the formation of the semiconductor region 31 from the first trench 33.

In step S2 of FIG. 8B, a doped semiconductor layer 81 (of the second conductivity type) is formed by epitaxy on at least part of the peripheral side surface of the first trench 33, and, in an embodiment, on the entire peripheral side surface of the first trench 33. Beneficially, the etching mask 80 is retained at this step to prevent growth of the doped conductive layer 81 on the upper face of the stack (this is referred to as selective epitaxy). The doped semiconductor layer 81 is, for example, between 50 nm and 200 nm thick. Its concentration of doping impurities is beneficially less than 5.10¹⁹ cm³ to avoid obtaining a too strong electric field in the PN junction.

Then, in step S3 of FIG. 8C, diffusion annealing is performed to diffuse doping impurities from the doped semiconductor layer 81 laterally into the substrate 30, thus obtaining the semiconductor region 31. In an embodiment, the doping impurities are diffused over a distance d of between 100 nm and 1 μm, this distance being measured from the peripheral side surface of the first trench 33.

Thus, when the doped semiconductor layer 81 covers the entire peripheral side surface of the first trench 33, the semiconductor region 31 is in the form of a ring around the first trench 33 (this ring having a cross-section of width I=d of between 100 nm and 1 μm).

Diffusion annealing is, in an embodiment, performed at a temperature of between 800° C. and 1100° C. Its duration can be between 10 s and 90 min.

Diffusion annealing has the effect of smoothing doping of the semiconductor region 31 to soften the electric field (thus avoiding band-to-band tunneling) and moving the depletion zone of the PN junction away from the etching zone of the first trench 33.

In one alternative embodiment of steps S2 and S3, the semiconductor region 31 is formed by gas phase diffusion doping from the side surface of the first trench 33.

FIG. 8D represents an optional step S4 of the manufacturing method, of forming, at the interface between the semiconductor region 31 and the first trench 33, an additional doped semiconductor layer 82 (referred to as an interface layer), in order to enhance passivation of the defects caused by etching the first trench 33 (said passivation being achieved by the first charge accumulation layer formed by virtue of the passivation structure 32). The additional doped conductive layer 82 is, for example, between 25 nm and 200 nm thick. Its concentration of doping impurities is beneficially greater than or equal to 5.10¹⁸ cm⁻³.

Steps S5 and S6 of FIGS. 8E and 8F are related to the formation of the capacitive effect passivation structure 32.

In step S5 of FIG. 8E, the first dielectric layer 321 is formed on said at least one part of the peripheral side surface of the first trench 33, and, in an embodiment, on the entire peripheral side surface of the first trench 33. The first dielectric layer 321 is, in an embodiment, formed by thermal oxidation of the material of the semiconductor region 31. Its thickness is, for example, between 1 nm and 5 nm.

Then, at S6 (see FIG. 8F), the remaining part (the core) of the first trench 33 is filled with an electrically charged material to form the first charged layer 322. The technique used may be Atomic Layer Deposition (ALD), which is a conformal deposition technique.

After removing the etching mask 80, the passivation structure 32 is complete and can be used as such. The method then subsequently comprises a step of forming the second contacting zone 372 in the semiconductor region 31.

However, it is possible to go further in the integration to minimise the surface area occupied by the diode, by forming the second contacting zone 372 in the first trench 33.

Steps S7 to S9 in FIGS. 8G to 8I are thus related to the formation of the second contacting zone 372 at the top of the first trench 33.

After the step S6 of filling the first trench 33 with the electrically charged material, the method comprises a step S7 represented by FIG. 8G and consisting in etching an upper portion of the first charged layer 322 (this is known as “recess”). The etched portion of the first charged layer 322 can have a thickness of between 50 nm and 200 nm. Etching of the first charged layer 322 is, in an embodiment, selective relative to the first dielectric layer 321.

Then, at S8 (see FIG. 8H), the first dielectric layer 321 is etched into the upper part of the first trench 33, until (part of) the side surface of the semiconductor region 31 is exposed. Etching the first dielectric layer 321 is, in an embodiment, selective relative to the semiconductor region 31. Beneficially, the hard mask 80 is simultaneously removed (the first dielectric layer 321 and the hard mask 80 can especially both be made of an oxide, such as SiO₂).

Finally, at S9 (see FIG. 8I), a doped semiconductor material (such as doped polycrystalline silicon) is deposited into the upper part of the first trench 33 (with the electrically charged material emptied), so as to plug the first trench 33 and form the second contacting zone 372. The doped semiconductor material may be deposited so as to form a planar surface with the upper face of the stack (or the upper face of the substrate, in the absence of the first electric field reducing layer 34). Alternatively, the deposit may form an excess thickness on the upper face of the stack, in which case a planarisation operation (for example by chemical mechanical polishing) is carried out to obtain a planar surface with the upper face of the stack.

The diode 3 of FIG. 5 may be manufactured by replacing the electrically charged material with an electrically conductive material (e.g. metal, doped polysilicon) to form the electrode 322′ in step S6 of FIG. 8F and omitting subsequent steps S7-S9. As a replacement, the method will comprise a step of forming the second contacting zone 372 in the semiconductor region 31, for example by implanting doping impurities.

The semiconductor region 31 and the capacitive effect passivation structure 32 (obtained according to any of the methods described above) together form a structure known as a Diffused Capacitive Deep Trench (DCDT).

The method for manufacturing the diode 3 according to FIG. 3 or FIG. 5 further comprises a step of forming the peripheral isolation structure 38 delimiting the active region 30′ of the substrate 30. The peripheral isolation structure 38 may be formed in a way similar to the capacitive effect passivation structure 32, by etching the second trench 39 into the substrate 30 (and the first electric field reduction layer 34, if applicable), then filling (successively) the second trench 39 with the following layers:
the second dielectric layer 381;
the second electrically charged layer 382 or the second electrode 382′; and beneficially;
the opaque material layer 383.

The peripheral isolation structure 38 is, in an embodiment, formed after the capacitive effect passivation structure 32 (i.e. after step S6 of FIG. 8F). This relaxes the constraints on the formation of the peripheral isolation structure 38, which does not have to withstand the high thermal budget required to form the capacitive effect passivation structure 32. In particular, this allows the use of a metal opaque layer in the peripheral isolation structure 38.

The first and second contact zones 371-372 are, in an embodiment, formed as late as possible in the manufacturing method (but before the so-called metallisation step for forming the contact pads), i.e. after formation of the capacitive effect passivation structure 32 and the peripheral isolation structure 38. This limits the thermal budget seen by these zones and restricts the diffusion of their doping impurities.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The present invention has been described and illustrated in the present detailed description and in the figures of the appended drawings, in possible embodiments. The present invention is not however limited to the embodiments described. Other alternatives and embodiments may be deduced and implemented by those skilled in the art on reading the present description and the appended drawings.

In the claims, the term “includes” or “comprises” does not exclude other elements or other steps. The different characteristics described and/or claimed may be beneficially combined. Their presence in the description or in the different dependent claims do not exclude this possibility. The reference signs cannot be understood as limiting the scope of the invention.

1. A single photon avalanche diode comprising:
a semiconductor substrate doped with a first conductivity type and having a first face and a second face opposite to the first face;
a peripheral isolation structure delimiting an active region of the semiconductor substrate, the peripheral isolation structure extending into the semiconductor substrate from the first face towards the second face;
a semiconductor region doped with a second conductivity type opposite to the first conductivity type, extending into the active region of the semiconductor substrate from the first face towards the second face, and
a capacitive effect passivation structure disposed inside a first trench which extends into the semiconductor region, the capacitive effect passivation structure extending in contact with the semiconductor region and being configured to form a first electric charge accumulation layer in the semiconductor region at the interface with the first trench.

2. The single photon avalanche diode according to claim 1, wherein the capacitive effect passivation structure comprises a first dielectric layer and a first electrically charged layer separated from the semiconductor region by the first dielectric layer.

3. The single photon avalanche diode according to claim 1, wherein the capacitive effect passivation structure comprises a first dielectric layer and an electrode separated from the semiconductor region by the first dielectric layer.

4. The single photon avalanche diode according to claim 1, wherein the peripheral isolation structure is disposed inside a second trench and configured to form a second electric charge accumulation layer in the semiconductor substrate at the interface with the second trench.

5. The single photon avalanche diode according to claim 4, wherein the peripheral isolation structure comprises a second dielectric layer and a second electrically charged layer separated from the active region of the semiconductor substrate by the second dielectric layer.

6. The single photon avalanche diode according to claim 5, wherein the peripheral isolation structure further comprises an opaque material layer separated from the active region of the semiconductor substrate by the second electrically charged layer and the second dielectric layer.

7. The single photon avalanche diode according to claim 1, wherein the semiconductor region surrounds the capacitive effect passivation structure.

8. The single photon avalanche diode according to claim 1, further comprising a contacting zone of the semiconductor region, the contacting zone being disposed on the capacitive effect passivation structure in the first trench.

9. A method for manufacturing a single photon avalanche diode, comprising:
etching a first trench in a semiconductor substrate doped with a first conductivity type and having a first face and a second face opposite to the first face, the first trench extending from the first face towards the second face;
after etching the first trench, forming a semiconductor region doped with a second conductivity type opposite to the first conductivity type, the semiconductor region being formed from the first trench, partly delimited by the first trench and extending into the semiconductor substrate from the first face towards the second face;
forming a capacitive effect passivation structure in the first trench, the capacitive effect passivation structure being configured to form a first electric charge accumulation layer in the semiconductor region at the interface with the first trench, and
forming a peripheral isolation structure delimiting an active region of the semiconductor substrate, the peripheral isolation structure extending into the semiconductor substrate from the first face towards the second face.

10. The method according to claim 9, wherein forming the semiconductor region comprises:
epitaxially forming a doped semiconductor layer on a side surface of the first trench, the doped semiconductor layer comprising doping impurities, and
performing diffusion annealing to laterally diffuse the doping impurities from the doped semiconductor layer into the semiconductor substrate.

11. The method according to claim 9, wherein the semiconductor region is formed by gas phase diffusion doping from a side surface of the first trench.
